(19) United States
(12) Patent Application Publication
(10) Pub. No.: US 2025/0166680 A1
(43) Pub. Date: May 22, 2025

(54) MEMORY DEVICES WITH FLYING DECORDER LINES AND METHODS FOR OPERATING THE SAME

(71) Applicant: Taiwan Semiconductor Manufacturing Company, Ltd., Hsinchu (TW)

(72) Inventors: Yen-Hsiang Huang, Hsinchu City (TW); Hui Pin Feng, Hsinchu City (TW); Jui-Che Tsai, Hsinchu City (TW); Chia-En Huang, Hsinchu City (TW); Che-Wei Chang, Hsinchu City (TW); Yih Wang, Hsinchu City (TW)

(73) Assignee: Taiwan Semiconductor Manufacturing Company, Ltd., Hsinchu (TW)

(21) Appl. No.: 18/511,652

(22) Filed: Nov. 16, 2023

(51) Int. Cl. G11C 8/10

(52) U.S. Cl. CPC G11C 8/10

(57) ABSTRACT

A semiconductor device includes a plurality of first decoder lines disposed in a first metallization layer and extending in a first direction. Each of the first decoder lines includes at least a first segment and a second segment operatively coupled to a plurality of first memory cells and a plurality of second memory cells, respectively. The first segment and second segment of each of the first decoder lines are arranged side-by-side along the first direction.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area.

### BRIEF DESCRIPTION OF THE DRAWINGS

Aspects of the present disclosure should be understood from the following detailed description with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a block diagram of a memory device, in accordance with various embodiments.

FIG. 2 illustrates a schematic diagram of an example word line (WL) decoder of a memory device, in accordance with various embodiments.

FIG. 3 illustrates a schematic diagram of example WL decoders, in accordance with various embodiments.

FIG. 4 illustrates a schematic diagram of an example WL decoder, in accordance with various embodiments.

FIG. 5 illustrates a schematic diagram of an example WL decoder and an example memory controller, in accordance with various embodiments.

FIG. 6 illustrates an example set of signals provided by a memory controller, in accordance with various embodiments.

FIG. 7 illustrates a schematic diagram of an example WL decoder, in accordance with various embodiments.

FIG. 8 illustrates a schematic diagram of an example WL decoder, in accordance with various embodiments.

FIG. 9 illustrates a schematic diagram of an example WL decoder, in accordance with various embodiments.

FIG. 10 illustrates a schematic diagram of an example WL decoder, in accordance with various embodiments.

FIG. 11 illustrates a flow of an example method for operating a WL decoder, in accordance with some embodiments.

FIG. 12 illustrates a flow of an example method for forming a memory device, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” “top,” “bottom,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As integrated circuit technology advances, integrated circuit features have been decreasing, thereby allowing more circuitry to be implemented in an integrated circuit. While implementing memory devices in an integrated circuit, it may encounter various challenges. For example, in a word line decoder, where a significantly large number of metal lines are used, the metal tracks (e.g., decoder lines) may take a large space, and/or a parasitic RC value may be too large. This may cause delay in providing WL decode signals and thus increased access time and setup time.

The present disclosure provides various embodiments of a memory device and a word line decoder. Techniques disclosed herein provide solutions to reduce a RC value in a word line decoder, thereby reducing the RC delay in providing WL decode signals and improving the access time and setup time. Techniques disclosed herein include employing M4 tracks along with M2 tracks (e.g., running M2 tracks and M4 tracks in parallel) for signal connections wherein the M4 tracks are disposed vertically above the M2 tracks. This allows for reduction in a parasitic resistance, while sharing a space (e.g., 50% reduction in a back-end area for the metal lines). The arrangement of M2 tracks, M4 tracks, and controlled dimensions (e.g., width) thereof provides design flexibility that can be adopted according to various situations (e.g., resistance dominant, back-end capacitance dominant, front-end capacitance dominant, etc.). Techniques disclosed herein can be applied in different memory technologies, including SRAM, RRAM, MRAM, phase-change memory, NVM, NOR, NAND, e-fuse, OTP, BEOL memory, etc.

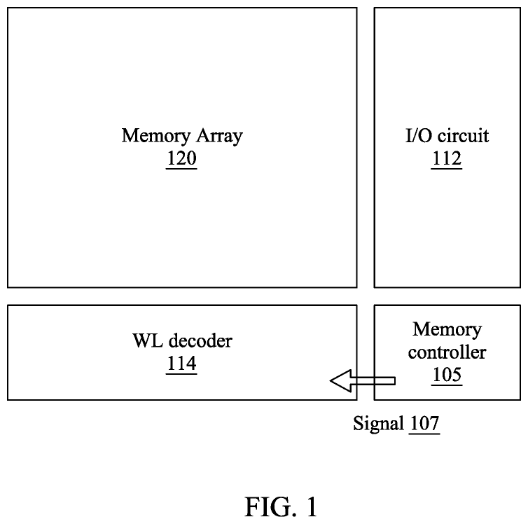

FIG. 1 illustrates a block diagram of a memory device 100, in accordance with various embodiments. The memory device 100 includes a memory array 120, a memory controller 105, an input/output (I/O) circuit 112, and a word line (WL) decoder 114. Despite not being explicitly shown in FIG. 1, the memory device 100 may include other components (e.g., a bit line controller, etc.). Despite not being explicitly shown in FIG. 1, the components of the memory device 100 may be operatively coupled to each other and to the memory controller 105. For example, a heater may be included and thermally coupled at least to the memory array 120, while the memory controller 105, the I/O circuit 112, the WL decoder 114, etc. may be electrically coupled to the memory array 120, in some embodiments. Although, in the illustrated example of FIG. 1, the component are shown as separate blocks for the purpose of clear illustration, in some other embodiments, some or all of the components shown in FIG. 1 may be integrated together. For example, the memory array 120 may include the I/O circuit 112 embedded therein.

The memory array 120 is embodied as a semiconductor memory device. The memory array 120 includes a plurality of storage circuits or memory cells. The memory array 120 includes word lines WL0, WL1 . . . . WLJ (not shown), each extending in a vertical direction (e.g., Y-direction) and bit lines BL0, BL1 . . . . BLK (not shown), each extending in a horizontal direction (e.g., X-direction). The word lines WL and the bit lines BL may be conductive metals or conductive rails. In one configuration, each memory cell is coupled to a corresponding word line WL and a corresponding bit line BL, and can be operated according to voltages or currents through the corresponding word line WL and the corresponding bit line BL. In some embodiments, each bit line includes bit lines BL, coupled to one or more memory cells of a group of memory cells disposed along the horizontal direction (e.g., X-direction). The bit lines BL may receive and/or provide differential signals. Each memory cell may include a volatile memory, a non-volatile memory, or a combination of them. In some embodiments, each memory cell is embodied as a static random access memory (SRAM) cell or other type of memory cell.

The WL decoder 114 is a hardware component that can receive a signal 107 from the memory controller 105. The signal 107 can include a WL address of the memory array 120 and assert a conductive structure (e.g., a word line) at that row address. Although not depicted, the memory device may include a bit line (BL) decoder, a hardware component that can receive a column address of the memory array 120 and assert one or more conductive structures (e.g., a bit line, a source line) at that column address.

The I/O circuit 112 is a hardware component that can access (e.g., read, program) each of the memory cells in the memory array 120 asserted through the WL decoder 114 and the BL decoder. For example, a plural number of switch/selection transistors can form the I/O circuit 112. In some embodiments, the memory array 120 may be formed in a first region of a substrate, while the I/O circuit 112 may be formed in a second region of the substrate. The second region can be configured as a close-end or an open-end ring surrounding the first region.

The memory controller 105 is a hardware component that controls operations of the memory array 120. As shown in FIG. 1, the memory controller 105 can be physically located next to the WL decoder 114. The memory controller 105 includes and/or controls the BL decoder, the I/O circuit 112, the WL decoder 114, etc. In some examples, the BL decoder, the I/O circuit 112, the WL decoder 114, etc. may be embodied as logic circuits, analog circuits, or a combination of them. In one configuration, the WL decoder 114 is a circuit that provides a voltage or current through one or more WLs of the memory array 120, and the BL decoder (not shown) is a circuit that provides or senses a voltage or current through one or more BLs of the memory array 120. The WL decoder 114 can include a plurality of metal tracks and a plurality of drivers to provide a voltage or current to the memory array 120. For example, the WL decoder 114 can include at least a first set of metal tracks to receive the signal 107 from the memory controller 105, and can include at least a second set of metal tracks to transmit decode signals to the memory array 105. The memory controller 105 can provide decoder signals to different memory cells through different pairs of the first set and the second set of metal tracks. In one configuration, the memory controller 105 can control a voltage provision circuit included therein to provide a voltage signal to the BL decoder, the I/O circuit 112, the WL decoder 114, etc. In some embodiments, such a voltage provision circuit is embodied as or includes a processor and a non-transitory computer readable medium storing instructions when executed by the processor cause the processor to execute one or more functions of the memory controller 105 described herein. The BL decoder may be coupled to BLs of the memory array 120, and the WL decoder 114 may be coupled to WLs of the memory array 120. In some embodiments, the memory controller 105 includes more, fewer, or different components than shown in FIG. 1.

The WL decoder 114 includes a number of frontside metallization layers. Each of the frontside metallization layers includes a number of back-end interconnect structures, metal lines (e.g., decoder lines) and via structures, embedded in a corresponding dielectric material (e.g., an inter-metal dielectric (IMD)). For example, the memory device 100 includes any number of frontside metallization layers (e.g., M0, M1, M2, etc.). Each of the frontside metallization layers includes a plurality of metal lines (e.g., decoder lines). The frontside metallization layer M0 includes decoder lines (which are sometimes referred to as “M0 tracks”), and via structures (which are sometimes referred to as “V0”); the frontside metallization layer M1 includes decoder lines (which are sometimes referred to as “M1 tracks”), and via structures (which are sometimes referred to as “V1”); and the frontside metallization layer M2 includes decoder lines (which are sometimes referred to as “M2 tracks”). Likewise, the memory device 100 may include any number of frontside metallization layers each including a plurality of decoder lines and a plurality of via structures.

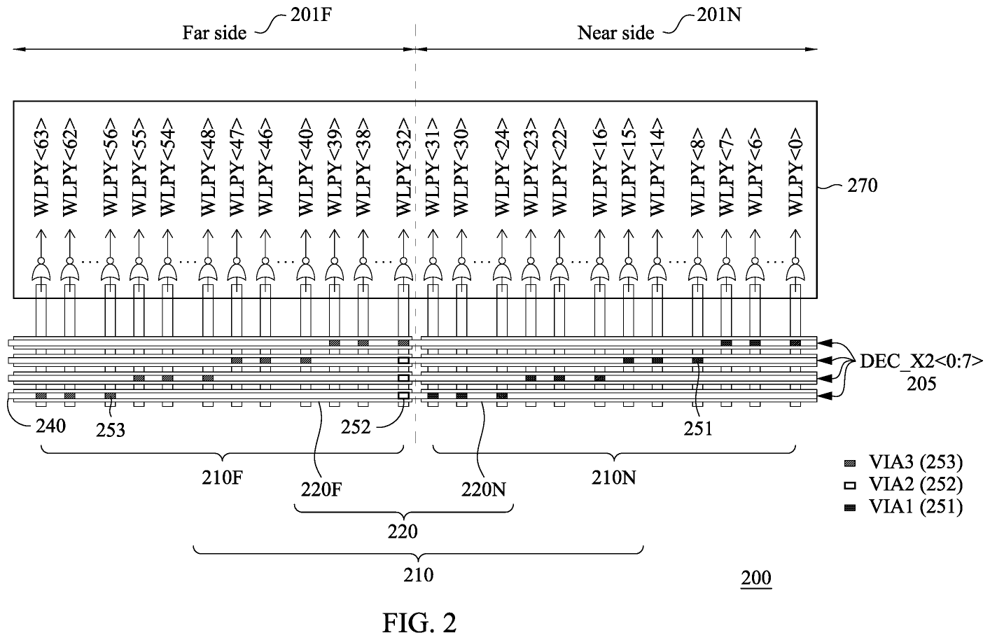

FIG. 2 illustrates a schematic diagram of an example WL decoder 200 of a memory device (e.g., the memory device 100), in accordance with various embodiments. The WL decoder 200 is an example WL decoder of the WL decoder 114. The WL decoder 200 includes a plurality of metallization layers each including a plurality of decoder lines.

The WL decoder 200 includes a plurality of first decoder lines disposed in a first metallization layer and extending in a first direction (e.g., X-direction). The first decoder lines may be M2 tracks 220. As shown, each of the M2 tracks 220 includes at least a first segment and a second segment operatively coupled to a plurality of first memory cells and a plurality of second memory cells, respectively. The first segment and second segment of each of the M2 tracks 220 are arranged side-by-side along the first direction. The first segment may be M2 tracks 220N located at a near side 201N, and the second segment may be M2 tracks 220F located at a far side 201F. The M2 tracks 220N, 220F can be collectively referred to as the M2 tracks 220. The WL decoder 200 includes a plurality of second decoder lines disposed in a second metallization layer and extending in a second direction (e.g., Y-direction). The second decoder lines may be M1 tracks 210. The M1 tracks 210N are located at the near side 201N, and the M1 tracks 210F are located at the far side 201F. The M1 tracks 210N, 210F can be collectively referred to as the M1 tracks 210.

The first segment (e.g., 220N) of each of the M2 tracks 220 is operatively coupled to a first subset of the first memory cells through a first subset of the M1 tracks 210, and the corresponding second segment (e.g., 220F) of the M2 tracks 220 is operatively to a first subset of the second memory cells through a second subset of the M1 tracks 210. The first subset of the M1 tracks 210 and the second subset of the M1 tracks 210 are spaced from each other with one or more other subsets of the M1 tracks 210 along the first direction. In some examples, the second metallization layer (e.g., the M1 tracks) is disposed vertically below the first metallization layer (e.g., the M2 tracks).

The WL decoder 200 includes a plurality of third decoder lines disposed in a third metallization layer and extending in the first direction. The third decoder lines may be M4 tracks 240. Each of the plurality of the M4 tracks extends across the first segment (e.g., 220N) and the second segment (e.g., 220F) of the corresponding one of the plurality of the M2 tracks 220. In some examples, the M4 tracks 240 are disposed vertically above the M2 tracks 220. In some examples, each of the plurality of the M4 tracks 240 is operatively coupled only to the second segment (e.g., 220F) of the corresponding M2 track. Although not depicted in FIG. 2, in some examples, the WL decoder 200 may include other metallization layers (e.g., M3 tracks disposed between the M2 tracks 220 and the M1 tracks 210). In some examples, the sheet resistance of the M4 tracks 240 may be less than that of the M2 tracks 220, thereby reducing a parasitic resistance of the decode lines.

The WL decoder 200 includes a plurality of via structures, including first via structures 251, second via structures 252, and third via structures 253 (collectively referred to as via structures 250). The via structures 250 can operably connect different metallization layers. Each of the first via structures 251 can operably connect one of the M1 tracks 210 to one of the M2 tracks 220. In some examples, each of the first via structures 251 can operably connect one of the M1 tracks 210N (located at the near side 201N) to one of the M2 tracks 220N (located at the near side 201N). Each of the second via structures 252 can operably connect one of the M2 tracks 220 with one of the M3 tracks (not shown). Each of the third via structures 253 can operably connect one of the M3 tracks (not shown) to one of the M4 tracks 240. In some examples, each of the third via structures 253 can operably connect one of the M3 tracks (not shown) to one of the M4 tracks 240F (located at the far side 201F). As shown in FIG. 2, the WL decoder 200 can include or be connected to WLPY circuits 270. The memory controller (e.g., 105) can provide decode signals (e.g., 107, 205) to the memory array 120 through the metal tracks (e.g., M1, M2, etc.) and the WLPY circuits 270. The WLPY circuits 270 can include or be implemented as logic circuits (e.g., NOR gates, AND gates, etc.). For example, each of the WLPY circuits 270 can receive corresponding decode signals, process the signals through one or more of logic circuits (e.g., NOR gates, AND gates, etc.), and provide the processed signal to a WL driver.

In some examples, each of the M2 tracks 220 has a first width extending in the second direction (e.g., Y-direction) perpendicular to the first direction (e.g., X-direction), and each of the M4 tracks 240 has a second width in the second direction. In some examples, the second width is less than the first width.

In some examples, the memory controller 105 of FIG. 1 can be physically located next to the WL decoder 200. For example, the memory controller 105 can be physically located next to the M2 tracks 210N (located at the near side 201N), with the M2 tracks 210F (located at the far side 210F) disposed opposite the M2 tracks 210N from the memory controller 105. The memory controller 105 can provide decode signals 205 (e.g., DEC_X2<0:7>) to activate a first set of memory cells and a second set of memory cells through at least the M2 tracks 220. The decode signals 205 may be part of the signal 107 that the memory controller 105 can provide to the WL decoder 114. For example, the memory controller 105 can provide the signals DEC_X2<0:3> to WLPY<0:31> of the WLPY circuits 270 through the M2 tracks 220N at the near side 201N, and provide the signals DEC_X2<4:7> to WLPY<32:63> of the WLPY circuits 270 through the M2 tracks 220F, together with the M4 tracks 240, at the far side 201F. In various embodiments, the M2 tracks 220F and the M4 tracks 240 run and are connected in parallel with each other. By connecting the M2 tracks 220F and the M4 tracks 240 in parallel, the parasitic resistance at the far side 201F can be advantageously reduced.

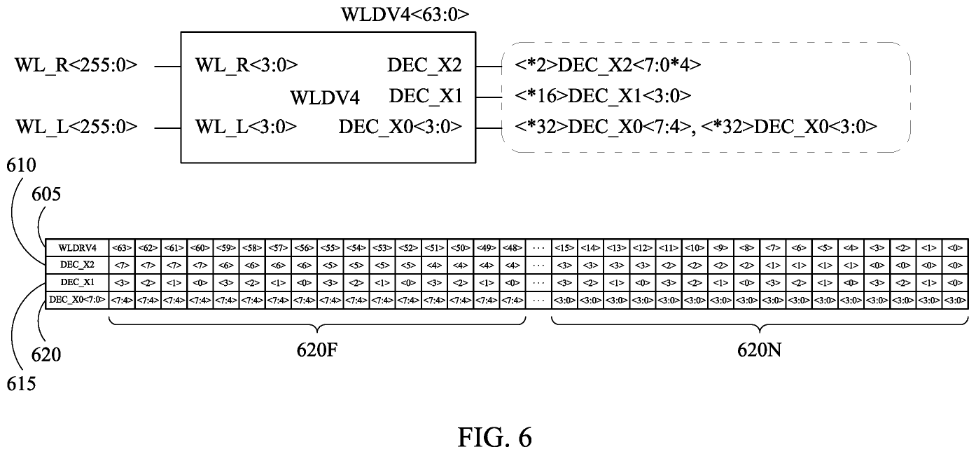

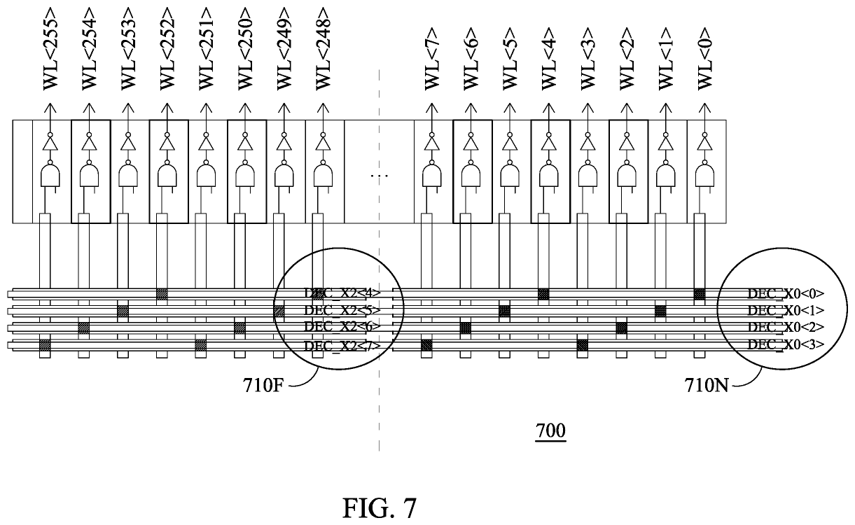

In some embodiments, each of the WLPY circuits 270 may be implemented as a NOR gate. Each of the WLPY circuits 270 has a first input and a second input that are configured to receive a corresponding bit of the decode signal 205 (e.g., DEC_X2<0:7>) and a corresponding bit of another decode signal (e.g., DEC_X1), respectively. Each of the WLPY circuits 270 can NOR the received bits and provide an output signal, which can be further AND'ed with yet another decode signal (e.g., DEC_X0) to assert a certain word line WL. Details of the decode signals, DEC_X2, DEC_X1, and DEC_X0 will be discussed in FIG. 6 and FIG. 7.

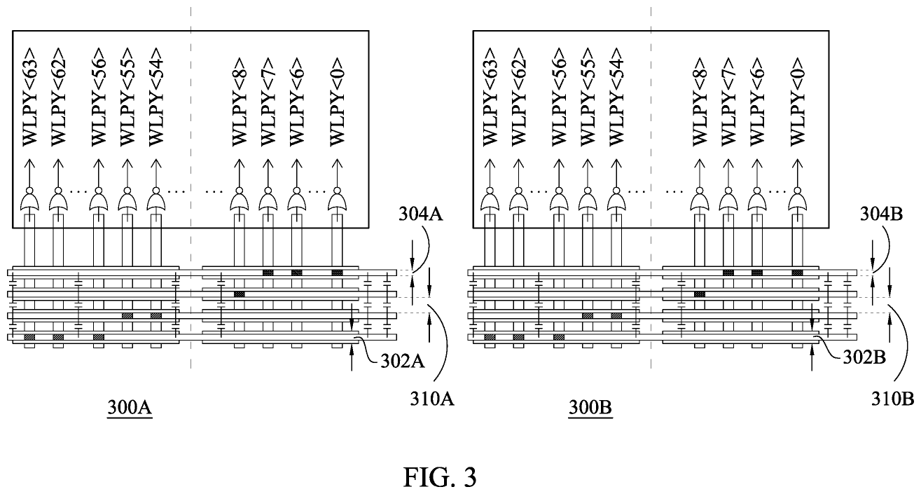

FIG. 3 illustrates a schematic diagram of example WL decoders 300A and 300B, in accordance with various embodiments. The WL decoders 300A and 300B may be substantially similar to or identical to the WL decoder 200. For example, the WL decoders 300A and 300B may be an example of the WL decoder 200. For example, the WL decoders 300A and 300B include M1 tracks (e.g., 210), M2 tracks (e.g., 220), M4 tracks (e.g., 240), and WLPY circuits (e.g., 270).

In the WL decoder 300A, the M2 tracks (e.g., 220) has a width 302A, the M4 tracks (e.g., 240) has a width 304A, where the width is in the second direction (e.g., Y-direction). A distance (in the second direction, Y-direction) between the M4 tracks 240 (and/or the M2 tracks 220) is a first distance 310A. In the WL decoder 300B, the M2 tracks (e.g., 220) has a width 302B, the M4 tracks (e.g., 240) has a width 304B, where the width is in the second direction (e.g., Y-direction). A distance (in the second direction, Y-direction) between the M4 tracks 240 (and/or the M2 tracks 220) is a second distance 310B.

In some examples, the first distance 310A in the WL decoder 300A is less than the second distance 310B in the WL decoder 300B. In some examples, the width 304A of the M4 tracks (e.g., 240) in the WL decoder 300A is greater than the width 304B of the M4 tracks (e.g., 240) in the WL decoder 300B. In some examples, the width 302A of the M2 tracks (e.g., 220) in the WL decoder 300A is greater than the width 302B of the M2 tracks (e.g., 220) in the WL decoder 300B.

The distance (e.g., 310A, 310B) between the M4 tracks (e.g., 240) (and/or the distance between the M2 tracks (e.g., 220)) can be designed to reduce a parasitic capacitance between the M4 tracks (and/or the M2 tracks). In some examples, the width (e.g., 304A) of the M4 tracks in the WL decoder 300A can be reduced to increase the distance (e.g., 310A) between the M4 tracks. This allows for reduction in a parasitic capacitance while not increasing the resistance by use of the M4 tracks (e.g., 240).

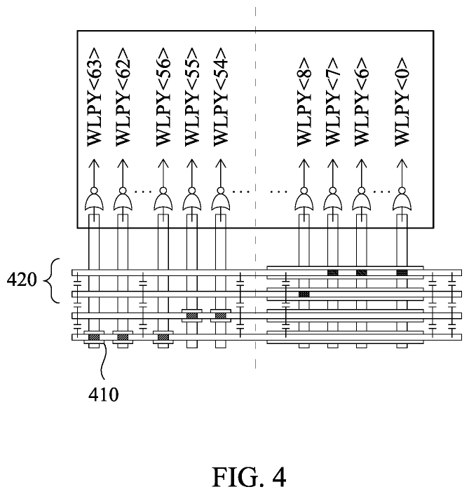

FIG. 4 illustrates a schematic diagram of an example WL decoder 400, in accordance with various embodiments. The WL decoder 400 may be substantially similar to or identical to the WL decoder 200. For example, the WL decoder 400 may be an example of the WL decoder 200. For example, the WL decoder 400 includes M1 tracks (e.g., 210), M2 tracks (e.g., 220N) at the near side (e.g., 201N), pieces of M2 tracks (e.g., 220F) at the far side (e.g., 201F), M4 tracks (e.g., 240), and WLPY circuits (e.g., 270).

As shown in FIG. 4, the WL decoder 400 includes M2 pieces 410 at the far side 201F, while having the M2 tracks (e.g., 220N) at the near side 201N. Each of the M2 pieces 410 may be a portion of the M2 tracks (e.g., 220F) at the far side 201F. In the WL decoder 400, the M2 tracks (e.g., 220F) at the far side 201F are removed, except for the M2 pieces 410 where each of the M4 tracks (e.g., 240) is coupled to the M1 tracks (e.g., 210F) at the far side 201F. As shown, the M2 pieces 410 can be omitted on the first two rows 420, in which the M4 tracks 240 are not coupled to the corresponding M1 tracks 210F at the far side 201F and coupled only to the corresponding M2 tracks 220N at the near side 201N.

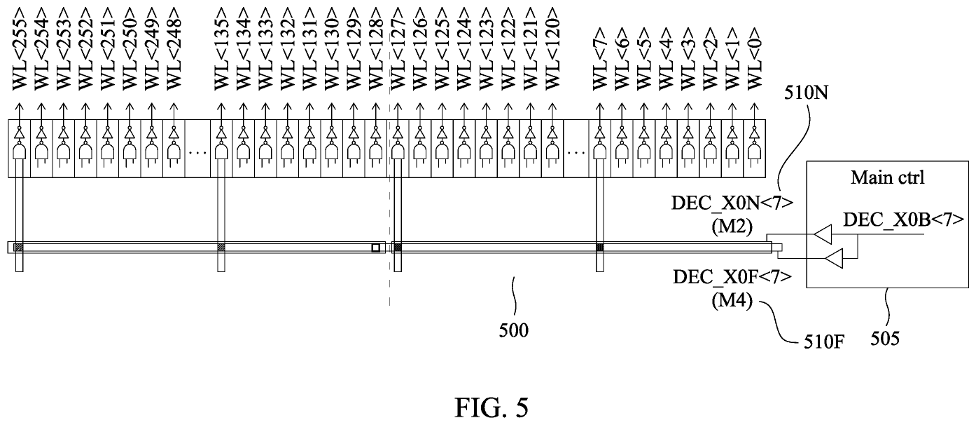

FIG. 5 illustrates a schematic diagram of an example WL decoder 500 and an example memory controller 505, in accordance with various embodiments. The WL decoder 500 may be substantially similar to or identical to the WL decoder 200. For example, the WL decoder 500 may be an example of the WL decoder 200. For example, the WL decoder 500 includes M1 tracks (e.g., 210), M2 tracks (e.g., 220), M4 tracks (e.g., 240), and WLPY circuits (e.g., 270). In FIG. 5, only one line of M2 tracks (e.g., 220) and one line of M4 tracks (e.g., 240) are shown for illustrative purposes. The memory controller 505 may be substantially similar to or identical to the memory controller 105. For example, the memory controller 505 can provide decode signals (e.g., 107, 205) to the WL decoder 500.

The memory controller 505 can separate one signal to two signals. For example, the memory controller 505 can separate DEC_X0B<7> into DEC_X0N<7> 510N and DEC_X0F<7> 510F, send DEC_X0N<7> 510N to the near side (e.g., 201N) through the M2 tracks (e.g., 220N) and send DEC_X0F<7> 510F to the far side (e.g., 201F) through the M4 tracks (e.g., 240) and the M2 tracks (e.g., 220F). In this case, memory cells at the far side (e.g., 220F) can be driven through the M4 tracks, and the delay in providing decode signals can be reduced.

FIG. 6 illustrates an example set of signals provided by a memory controller (e.g., 105), in accordance with various embodiments. The memory controller (e.g., 105) can provide a set of signals (e.g., 107) to control the memory array (e.g., 120) through a number of WLDRV4's 605. The WLDRV4 605 includes a plurality of WL drivers (e.g., 64 WL drivers, WLDV4<63:0>), each configured to receive a portion of the set of signals (e.g., 107) from the corresponding WLPY circuits (e.g., 270) and assert one of a subset of WL signals (e.g., 4 WL signals) at a time to control a corresponding cell of the memory array (e.g., 120).

More specifically, the memory controller (e.g., 105) can provide the set of signals (e.g., 107) including DEC_X2 610, DEC_X1 615, and DEC_X0 620 to the WLPY circuits (e.g., 270) through metal tracks (e.g., M1 tracks, M2 tracks, etc.). A first set of logic circuits (e.g., NOR gates) in the WLPY circuits (e.g., 270) can receive and process DEC_X2 610 (e.g., DEC_X2<7:0>) and DEC_X1 620 (e.g., DEC_X1<3:0>) to provide an output signal. The output signal can be further processed with DEC_X0 to provide a WL signal to assert a certain word line.

A sequence of one (e.g., DEC_X0 620) of the signals can be changed such that the memory controller (e.g., 105) can provide the near side (e.g., 201N) and the far side (e.g., 201F) with separate signals. That is, as shown in FIG. 6, the sequence of DEC_X0 620 can be adjusted such that the memory controller (e.g., 105) provides WLDRV4<63:48> with DEC_X0<7:4> at the far side (e.g., 201F) and provides WLDRV4<47:0> with DEC_X0<3:0> at the near side (e.g., 201N). This allows the memory controller (e.g., 105) to separate decode signals (e.g., 170) into two separate signals, each for the far side (e.g., 201F) and the near side (e.g., 201N), rather than providing the entire signals (e.g., DEC_X0<7:0>) to both the far side (e.g., 201F) and the near side (e.g., 201N).

For example, DEC_X2 610 may be, from WLDRV4<63> to WLDRV4<0>:
<7><7><7><7><6><6><6><6><5><5><5><5><4><4><4><4><3><3><3><3><2><2><2><2><1><1><1><1><0><0><0><0><7><7><7><7><6><6><6><6><5><5><5><5><4><4><4><4><3><3><3><3><2><2><2><2><1><1><1><1><0><0><0><0>.

For example, DEC_X1 615 may be, from WLDRV4<63> to WLDRV4<0>:
<3><2><1><0><3><2><1><0><3><2><1><0><3><2><1><0><3><2><1><0><3><2><1><0><3><2><1><0><3><2><1><0><3><2><1><0><3><2><1><0><3><2><1><0><3><2><1><0><3><2><1><0><3><2><1><0><3><2><1><0><3><2><1><0>.

For example, DEC_X0 620 may be <7><6><5><4> for each of WLDRV4<63:48>, and <3><2><1><0> for each of WLDRV4<31:0>.

FIG. 7 illustrates a schematic diagram of an example WL decoder 700, in accordance with various embodiments. The WL decoder 700 may be substantially similar to or identical to the WL decoder 200. For example, the WL decoder 700 may be an example of the WL decoder 200. For example, the WL decoder 700 includes M1 tracks (e.g., 210), M2 tracks (e.g., 220), M4 tracks (e.g., 240), and WLPY circuits (e.g., 270).

The memory controller (e.g., 105) (not shown) can provide signals DEC_X0<0:7> to the WL decoder 700. The memory controller can selectively provide a first portion 710N of the signals, e.g., DEC_X0<3:0> to the near side (e.g., 201N) through the M2 tracks (e.g., 220N) at the near side, and selectively provide a second portion 710F of the signals, e.g., DEC_X0<7:4> to the far side (e.g., 201F) through the M4 tracks (e.g., 240) at the far side. For example, as shown in the first row of the WL decoder 700, the memory controller can provide DEC_X0<4> to the far side (e.g., 201F) through the first row of the M4 tracks (e.g., 240F), while providing DEC_X0<0> to the near side (e.g., 201N) through the first row of the M2 tracks (e.g., 220N).

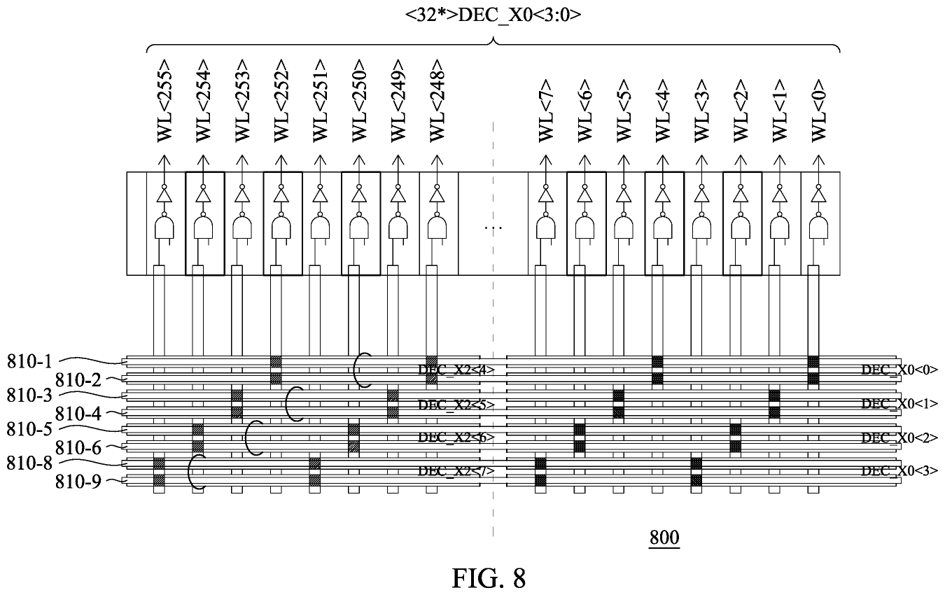

FIG. 8 illustrates a schematic diagram of an example WL decoder 800, in accordance with various embodiments. The WL decoder 800 may be substantially similar to or identical to the WL decoder 200. For example, the WL decoder 800 may be an example of the WL decoder 200. For example, the WL decoder 800 includes M1 tracks (e.g., 210), M2 tracks (e.g., 220), M4 tracks (e.g., 240), and WLPY circuits (e.g., 270).

The WL decoder 800 can include doubled metal tracks 810 for each of signals. As shown in FIG. 8, the WL decoder 800 can include the doubled tracks of M2 tracks (e.g., 220) and M4 tracks (e.g., 240) for each of DEC_X0<7:0>. More specifically, as a non-limiting example, the memory controller (e.g., 105) (not shown) can provide DEC_X0<0> through the M2 tracks in the doubled metal tracks 810-1 and 810-2 to the near side (e.g., 201N), and can provide DEC_X0<4> through the M4 tracks in the doubled metal tracks 810-1 and 810-2 to the far side (e.g., 201F). The doubled metal tracks 810 can further reduces a parasitic resistance.

In some examples, although not depicted, the WL decoder (e.g., 200) disclosed herein can have more than three metallization layers, and techniques disclosed herein can be applied in similar ways. For example, when the WL decoder includes more than three metallization layers, the WL decoder can include M2 tracks, M4 tracks, and M6 tracks, which can be provided with separate signals, DEC_X0<2:0>, DEC_X0<5:3>, and DEC_X0<7:6>, respectively.

In some examples, although not depicted, the WL decoder (e.g., 200) disclosed herein can be customized for different applications according to different metal RC values. For example, if a RC value of M2 tracks is significantly greater than that of M4 tracks, the ratio of the RC values between the M4 tracks and the M2 tracks can be adjusted to reduce/increase a usage ratio.

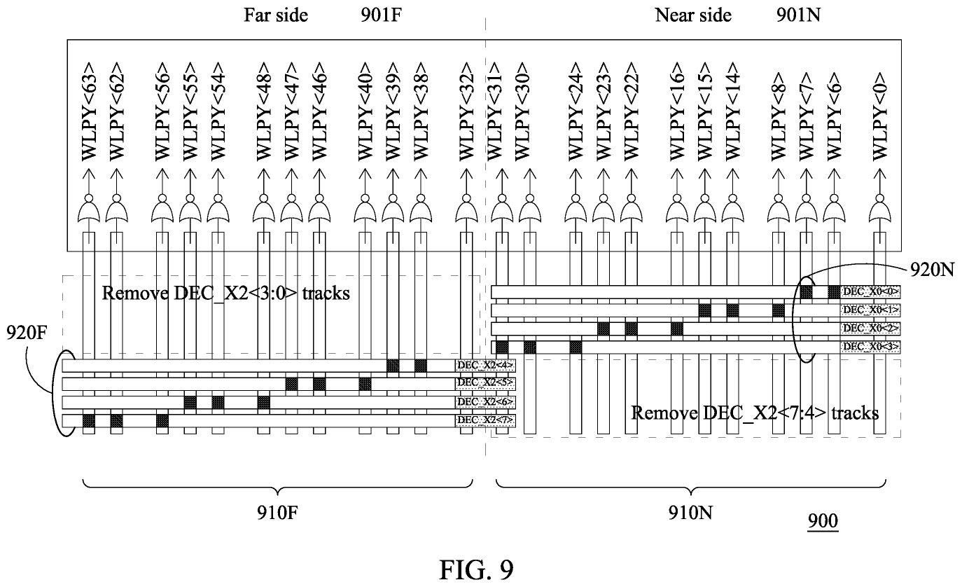

FIG. 9 illustrates a schematic diagram of an example WL decoder 900, in accordance with various embodiments. The WL decoder 900 may be substantially similar to or identical to the WL decoder 200, or a portion or an intermediate structure thereof. For example, the WL decoder 900 may be an example of the WL decoder 200. For example, the WL decoder 900 includes M1 tracks (e.g., 210) and WLPY circuits (e.g., 270).

The WL decoder 900 includes M2 tracks 920N at a near side 901N and M2 tracks 920F at a far side 901F (collectively referred to as M2 tracks 920). As shown, the M2 tracks 920N are located only at the near side 901N, and the M2 tracks 920F are located only at the far side 901F. The M2 tracks 920N are operably coupled with M1 tracks 910N at the near side 901N. The M2 tracks 920N can be provided with DEC_X2<3:0>. The M2 tracks 920F are operably coupled with M1 tracks 910F at the far side 901F. The M2 tracks 920F can be provided with DEC_X2<7:4>.

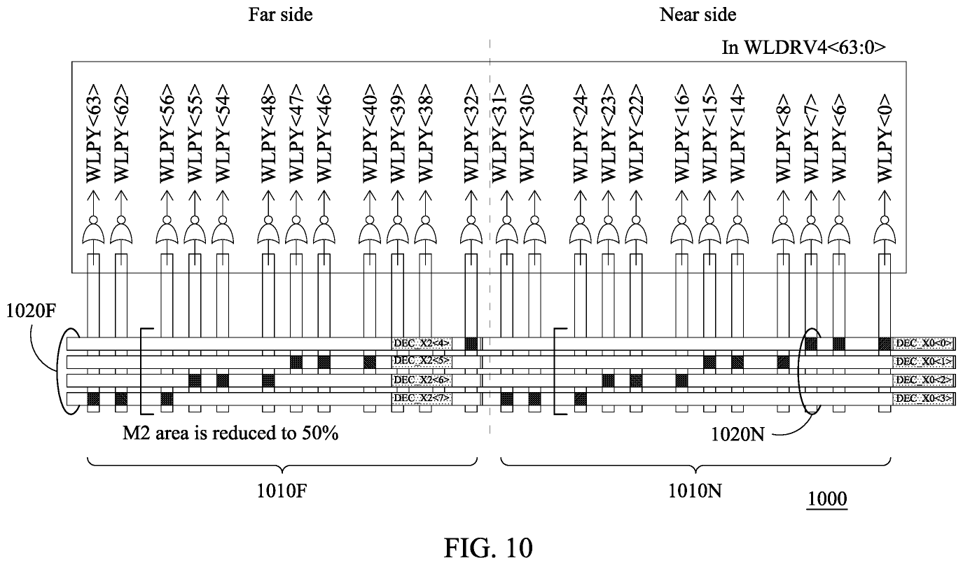

FIG. 10 illustrates a schematic diagram of an example WL decoder 1000, in accordance with various embodiments. The WL decoder 1000 may be substantially similar to or identical to the WL decoder 200 or the WL decoder 900, or a portion or an intermediate structure thereof. For example, the WL decoder 1000 may be an example of the WL decoder 200. For example, the WL decoder 1000 includes M1 tracks (e.g., 210) and WLPY circuits (e.g., 270).

The WL decoder 1000 may be a WL decoder in which the M2 tracks 920F of the WL decoder 900 are shifted up such that the M2 tracks 920F (1020F in FIG. 10) are aligned with the M2 tracks 920N (1020N in FIG. 10) in the first direction (e.g., X-direction). This allows for reduction in an area of the M2 tracks (e.g., 50% reduction in the second direction (e.g., Y-direction)).

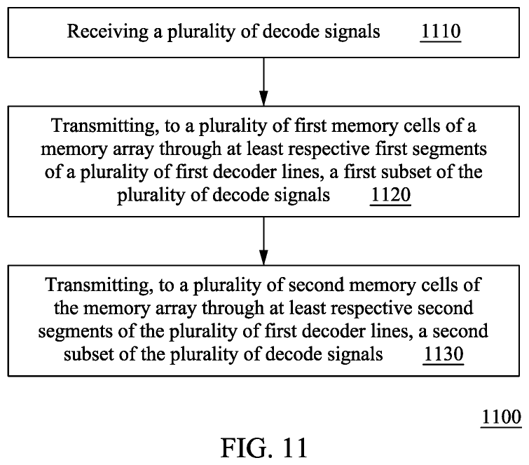

FIG. 11 illustrates a flow of an example method 1100 for operating a WL decoder, in accordance with some embodiments. The method 1100 can be performed with any of memory devices herein or a portion or a component thereof. For example, the method 1100 can be performed with any of the memory devices or a component thereof discussed with respect to FIG. 1 to FIG. 10. For example, at least one of operations of the method 1100 may be performed on a memory device (e.g., 100). Accordingly, the following discussion of the method 1100 may refer to some of the reference numerals used in FIG. 1 to FIG. 10 as a non-limiting example. Further, the method 1100 is merely an example, and is not intended to limit the present disclosure. It should thus be understood that additional operations may be provided before, during, and after the method 1100 of FIG. 11, and that some other operations may only be briefly described herein.

The method 1100 can start with operation 1110 of receiving a plurality of decode signals. In operation 1110, a WL decoder (e.g., 114, 200) may receive a plurality of decode signals from a memory controller (e.g., 105).

In response to receipt of the plurality of decode signals, the method 1100 can continue to operation 1120 of transmitting, to a plurality of first memory cells of a memory array through at least respective first segments (e.g., 220N) of a plurality of first decoder lines (e.g., M2 tracks 220), a first subset of the plurality of decode signals. The method 1100 can continue to operation 1130 of transmitting, to a plurality of second memory cells of the memory array through at least respective second segments (e.g., 220F) of the plurality of first decoder lines (e.g., M2 tracks 220), a second subset of the plurality of decode signals. The corresponding first segment (e.g., 220N) and the corresponding second segment (e.g., 220F) of each of the first decoder lines (e.g., M2 tracks 220) are physically separated from each other, and physically arranged side-by-side along a lateral direction (e.g., X-direction). Although operation 1130 is depicted and described following operation 1120, operation 1130 can be performed at the same time as operation 1120.

In some examples, the method 1100 may include transmitting, to the plurality of second memory cells further through a plurality of second decoder lines (e.g., M4 tracks 240), the second subset of the decode signals. The plurality of second decoder lines (e.g., M4 tracks 240) also extend along the lateral direction (e.g., X-direction), and each extend over the first segment (e.g., 220N) and second segment (e.g., 220F) of a corresponding one of the first decoder lines (e.g., M2 tracks 220). In some examples, the plurality of first decoder lines (e.g., M2 tracks 220) are disposed in a first metallization layer and the plurality of second decoder lines (e.g., M4 tracks 240) are disposed in a second metallization layer, the second metallization layer is vertically disposed over the first metallization layer.

In some examples, the method 1100 may include providing a plurality of signals to the first decoder lines (e.g., M2 tracks 220) and/or the second decoder lines (e.g., M4 tracks 240) with separate signals. For example, the method 1100 may include separating a signal into a first portion of signal (e.g., 510N) and a second portion of signal (e.g., 510F), thereby providing each signal to the first segment (e.g., 220N) and the second segment (e.g., 220F) of the first decoder lines (e.g., M2 tracks 220), respectively. The second portion of signal (e.g., 510F) can be provided to the second segment (e.g., 220F) of the first decoder lines (e.g., M2 tracks 220) through the second decoder lines (e.g., M4 tracks 240).

In some examples, the method 1100 may include providing a plurality of signals to the first decoder lines (e.g., M2 tracks 220) and/or the second decoder lines (e.g., M4 tracks 240), the plurality of signals re-sequenced according to arrangement of the decoder lines. For example, as shown in FIG. 6, the method 1100 may include changing sequences of signals (e.g., DEC_X0 in FIG. 6) to separate the same into a first subset (e.g., DEC_X0<3:0> 620N) of signals and a second subset (e.g., DEC_X0<7:4> 620F) of signals, providing the first subset of signals to the first segment (e.g., 220N), and providing the second subset of signals to the second segment (e.g., 220F) and the second decoder lines (e.g., M4 tracks 240). Likewise, the method 1100 may include changing sequences of other signals (e.g., 605, 610, 615, etc.).

In some examples, the method 1100 may include providing a plurality of signals to the first decoder lines (e.g., M2 tracks 220) and/or the second decoder lines (e.g., M4 tracks 240) with separate signals. For example, the method 1100 may include providing a first signal (e.g., 710N) to the first segment (e.g., 220N) of the first decoder lines (e.g., M2 tracks 220) while providing a second signal (e.g., 710F) through the corresponding second decoder lines (e.g., M4 tracks 240). In some examples, the method 1100 may include using more than one decoder lines for each signal. For example, the method 1100 may include doubling each of the first decoder lines (e.g., M2 tracks 220) and the second decoder lines (e.g., M4 tracks 240) for each signal.

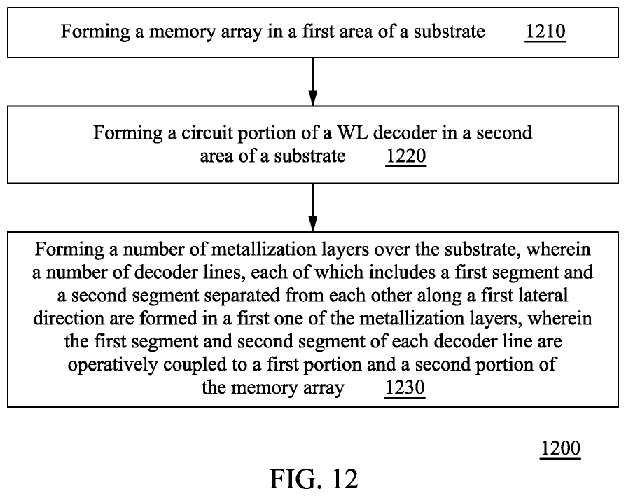

FIG. 12 illustrates a flow of an example method 1200 for manufacturing a memory device (e.g., 100), in accordance with some embodiments. The method 1200 can be performed to form any of memory devices herein or a portion thereof. For example, the method 1200 can be performed to form any of the memory devices or a component thereof discussed with respect to FIG. 1 to FIG. 10. For example, at least one of operations of the method 1200 may be performed to form a memory device (e.g., 100). Accordingly, the following discussion of the method 1200 may refer to some of the reference numerals used in FIG. 1 to FIG. 10 as a non-limiting example. Further, the method 1200 is merely an example, and is not intended to limit the present disclosure. It should thus be understood that additional operations may be provided before, during, and after the method 1200 of FIG. 12, and that some other operations may only be briefly described herein. The method 1200 can be performed simultaneously and/or in any order other than the order depicted in FIG. 12.

The method 1200 can start with operation 1210 of forming a memory array (e.g., 120) in a first area of a substrate.

The substrate may be a wafer, such as a silicon wafer, or a silicon-on-insulator (SOI) substrate. Generally, an SOI substrate includes a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof.

The memory array includes a plurality of memory cells. In some examples, each of the memory cells may be implemented as a six-transistor (6T) static random access memory (SRAM) cell that consists of six transistors (e.g., N1, N2, N3, N4, P1, and P2). However, it should be understood that the first to fourth memory cells may be implemented as other type of SRAM configurations than 6T, e.g., eight transistor (8T) or ten transistor (10T) configurations. In some examples, alternatively or additionally, the memory cells may be implemented as other type of memory cells such as, for example, dynamic random access memory (DRAM) cells, resistive random access memory (RRAM) cells, phase-change random access memory (PCRAM) cells, or magnetoresistive random access memory (MRAM) cells. In various embodiments, the memory cells may be formed along a major (e.g., frontside) surface of the substrate. According to fabrication of these memory cells (and corresponding memory arrays) may sometimes be referred to as front-end-of-line (FEOL) processing.

The method 1200 can continue to operation 1220 of forming a circuit portion (e.g., 270) of a WL decoder (e.g., 114) in a second area of the substrate. In some examples, at operation 1220, the method 1200 includes forming a plurality of logic components and/or a plurality of logic circuits (e.g., NOR gates, AND gates, etc.).

The method 1200 can continue to operation 1230 of forming a number of metallization layers (e.g., 210, 220, 240, etc.) over the substrate, wherein a number of decoder lines, each of which includes a first segment and a second segment separated from each other along a first lateral direction (e.g., X-direction) are formed in a first one of the metallization layers, wherein the first segment and second segment of each decoder line are operatively coupled to a first portion and a second portion of the memory array.

In some embodiments, the first segment may correspond to word lines WL and WLB operatively coupled to the first portion of the memory array, and the segment may correspond to word lines WL and WLB operatively coupled to the second portion of the memory array. The first and second segments can each extend along the lateral direction from a corresponding controller (e.g., 105), which is located immediately next to a first edge of the first segment along the lateral direction, and toward a second edge of the first segment opposite to the first edge. In some examples, the first and second segments can include one or more metal materials such as, for example, tungsten (W), copper (Cu), gold (Au), cobalt (Co), Ruthenium (Ru), or combinations thereof, and be fabricated using one or more damascene processes.

In some examples, at operation 1230, the method 1200 can include forming a plurality of second decoder lines in a second one of the metallization layers (e.g., 240), each of the second decoder lines operatively coupled to at least one of the first segment or the second segment. For example, the method 1200 can include forming a via structure that operatively couples the second decoder lines with the first segment and/or the second segment.

In one aspect of the present disclosure, a memory device is disclosed. The memory device includes a plurality of first decoder lines disposed in a first metallization layer and extending in a first direction. Each of the first decoder lines includes at least a first segment and a second segment operatively coupled to a plurality of first memory cells and a plurality of second memory cells, respectively. The first segment and second segment of each of the first decoder lines are arranged side-by-side along the first direction.

In another aspect of the present disclosure, a memory device is disclosed. The memory device includes a plurality of first memory cells and a plurality of second memory cells, a memory controller physically located next to the first memory cells, with the second memory cells physically located opposite the first memory cells from the memory controller along a first direction. The memory controller is configured to provide a plurality of decode signals to the memory array and a plurality of first decoder lines disposed in a first metallization layer and extending in the first direction. Each of the first decoder lines includes at least a first segment and a second segment operatively coupled to the first memory cells and the second memory cells, respectively.

In yet another aspect of the present disclosure, a method for operating a memory device is disclosed. The method includes receiving a plurality of decode signals, transmitting, to a plurality of first memory cells of a memory array through at least respective first segments of a plurality of first decoder lines, a first subset of the plurality of decode signals, and transmitting, to a plurality of second memory cells of the memory array through at least respective second segments of the plurality of first decoder lines, a second subset of the plurality of decode signals. The corresponding first segment and the corresponding second segment of each of the first decoder lines are physically separated from each other, and physically arranged side-by-side along a lateral direction.

In yet another aspect of the present disclosure, a method for manufacturing a memory device is disclosed. The method includes forming a memory array in a first area of a substrate, forming a circuit portion of a decoder in a second area of a substrate, and forming a number of metallization layers over the substrate, wherein a number of decoder lines, each of which includes a first segment and a second segment separated from each other along a first lateral direction, are formed in a first one of the metallization layers. The first segment and second segment of each decoder line are operatively coupled to a first portion and a second portion of the memory array, respectively.

As used herein, the terms “about” and “approximately” generally indicates the value of a given quantity that can vary based on a particular technology node associated with the subject semiconductor device. Based on the particular technology node, the term “about” can indicate a value of a given quantity that varies within, for example, 10-30% of the value (e.g., +10%, ±20%, or ±30% of the value).

As used herein, the terms “about” and “approximately” generally indicates the value of a given quantity that can vary based on a particular technology node associated with the subject semiconductor device. Based on the particular technology node, the term “about” can indicate a value of a given quantity that varies within, for example, 10-30% of the value (e.g., +10%, ±20%, or ±30% of the value).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A memory device, comprising:
a plurality of first decoder lines disposed in a first metallization layer and extending in a first direction;
wherein each of the first decoder lines includes at least a first segment and a second segment operatively coupled to a plurality of first memory cells and a plurality of second memory cells, respectively; and
wherein the first segment and second segment of each of the first decoder lines are arranged side-by-side along the first direction.

2. The memory device of claim 1, further comprising:
a plurality of second decoder lines disposed in a second metallization layer and extending in a second direction perpendicular to the first direction;
wherein the first segment of each of the first decoder lines is operatively coupled to a first subset of the first memory cells through a first subset of the second decoder lines, and the corresponding second segment of the first decoder line is operatively coupled to a first subset of the second memory cells through a second subset of the second decoder lines.

3. The memory device of claim 2, wherein the second metallization layer is disposed vertically below the first metallization layer.

4. The memory device of claim 2, wherein the first subset of the second decoder lines and the second subset of the second decoder lines are spaced from each other with one or more other subsets of the second decoder lines along the first direction.

5. The memory device of claim 1, further comprising:
a memory controller configured to provide a plurality of decode signals to the plurality of first memory cells and the plurality of second memory cells through at least the first decoder lines.

6. The memory device of claim 5, wherein the memory controller is physically located next to the first segments, with the second segments disposed opposite the first segments from the memory controller.

7. The memory device of claim 1, further comprising:
a plurality of third decoder lines disposed in a third metallization layer and extending in the first direction;
wherein each of the plurality of third decoder lines extends across the first and second segments of a corresponding one of the plurality of first decoder lines.

8. The memory device of claim 7, wherein the third metallization layer is disposed vertically above the first metallization layer.

9. The memory device of claim 7, wherein each of the plurality of third decoder lines is only operatively coupled to the second segment of the corresponding first decoder line.

10. The memory device of claim 7, wherein the plurality of first decoder lines each have a first width extending in a second direction perpendicular to the first direction and the plurality of third decoder lines each have a second width in the second direction, and wherein the second width is less than the first width.

11. A memory device, comprising:
a memory array including a plurality of first memory cells and a plurality of second memory cells;
a memory controller physically located next to the first memory cells, with the second memory cells physically located opposite the first memory cells from the memory controller along a first direction, wherein the memory controller is configured to provide a plurality of decode signals to the memory array; and
a plurality of first decoder lines disposed in a first metallization layer and extending in the first direction;
wherein each of the first decoder lines includes at least a first segment and a second segment operatively coupled to the first memory cells and the second memory cells, respectively.

12. The memory device of claim 11, wherein the first segment and second segment of each of the first decoder lines are arranged side-by-side along the first direction.

13. The memory device of claim 11, wherein a first subset of the plurality of decode signals are configured to activate the first memory cells, and a second subset of the plurality of decode signals are configured to activate the second memory cells.

14. The memory device of claim 11, further comprising:
a plurality of second decoder lines disposed in a second metallization layer and extending in a second direction perpendicular to the first direction;
wherein the first segment of each of the first decoder lines is operatively coupled to a first subset of the first memory cells through a first subset of the second decoder lines, and the corresponding second segment of the first decoder line is operatively coupled to a second subset of the second memory cells through a second subset of the second decoder lines.

15. The memory device of claim 14, further comprising:
a plurality of third decoder lines disposed in a third metallization layer and extending in the first direction;
wherein each of the plurality of third decoder lines extends across the first and second segments of a corresponding one of the plurality of first decoder lines.

16. The memory device of claim 15, wherein the second metallization layer is disposed vertically below the first metallization layer, and the third metallization layer is disposed vertically above the first metallization layer.

17. The memory device of claim 15, wherein each of the plurality of third decoder lines is only operatively coupled to the second segment of the corresponding first decoder line.

18. A method for forming a memory device, comprising:
forming a memory array in a first area of a substrate;
forming a circuit portion of a decoder in a second area of the substrate; and
forming a number of metallization layers over the substrate, wherein a number of decoder lines, each of which includes a first segment and a second segment separated from each other along a first lateral direction, are formed in a first one of the metallization layers,
wherein the first segment and second segment of each decoder line are operatively coupled to a first portion and a second portion of the memory array, respectively.

19. The method of claim 18, further comprising forming a plurality of second decoder lines in a second one of the metallization layers, each of the second decoder lines operatively coupled to at least one of the first segment or the second segment.

20. The method of claim 19, wherein the number of decoder lines each have a first width extending in a second direction perpendicular to the first direction and the plurality of second decoder lines each have a second width in the second direction, and wherein the second width is less than the first width.
